(19) United States
(12) Patent Application Publication
(10) Pub. No.: US 2024/0007120 A1
(43) Pub. Date: Jan. 4, 2024

(54) Time-Interleaved ADC

(71) Applicant: Nippon Telegraph And Telephone Corporation, Tokyo (JP)

(72) Inventors: Naoki Terao, Tokyo (JP); Munehiko Nagatani, Tokyo (JP); Hideyuki Nosaka, Tokyo (JP)

(21) Appl. No.: 18/253,530

(22) PCT Filed: Nov. 27, 2020
(86) PCT No.: PCT/JP2020/044224

§ 371 Date: May 18, 2023

(51) Int. Cl. H03M 1/12

(52) U.S. Cl. CPC H03M 1/1245; H03M 1/121

(57) ABSTRACT

A time interleaved ADC includes sub-ADCs that sample an analog input signal at a timing synchronized with a clock signal to convert the analog input signal into a digital output signal, delay circuits that apply a time difference to the analog input signal such that the analog input signal is input to each of the sub-ADCs with a delay of a first delay time in an arrangement order of the sub-ADCs, and delay circuits that apply a time difference to the clock signal such that the clock signal is input to each of the sub-ADCs with a delay of a second delay time in the arrangement order of the sub-ADCs.

### CROSS-REFERENCE TO RELATED APPLICATIONS

This application is a national phase entry of PCT Application No. PCT/JP2020/044224, filed on filed Nov. 27, 2020, which application is hereby incorporated herein by reference.

### TECHNICAL FIELD

The present invention relates to a semiconductor integrated circuit, and more particularly to an analog-to-digital converter (ADC).

### BACKGROUND

An analog-to-digital converter (ADC) is a circuit that periodically acquires (samples) an analog input signal at a timing synchronized with a clock signal, converts the analog input signal into a digital value, and outputs the digital value. In an example in FIG. 9, an ADC 100 samples an analog input signal in at a timing synchronized with a clock signal ck to convert the analog input signal in into a digital output signal out.

The number of times the ADC performs sampling per unit time is referred to as a sampling rate. Typically, a moment at which the ADC samples the analog input signal occurs once per cycle of the clock signal. Therefore, a sampling rate fs and a clock frequency fck have the following relationship.

fs=fck (1)

An ADC is used in a wide range of fields such as communication and measurement, but a required sampling rate has also increased with increases in speed and capacity of communication and an increase in performance of a measurement system.

As a method of increasing a sampling rate of an ADC, there is a method of increasing a clock frequency. However, when the clock frequency is increased, there is a problem that a requirement level in circuit design for a clock generation circuit or an ADC becomes strict.

Therefore, a configuration called time interleaving is used as a method of obtaining a sampling rate higher than a clock frequency without changing the clock frequency or a configuration of the ADC. An outline of time interleaving will be described with reference to FIG. 10. FIG. 10 schematically illustrates a configuration disclosed in Non Patent Literature 1.

In a time interleaved ADC illustrated in FIG. 10, a plurality of ADCs are simultaneously used. In the present specification, to prevent confusion, each ADC will be referred to as a sub-ADC. The number of sub-ADCs is referred to as a number of interleaves. In the example in FIG. 10, the number of interleaves is N (where N is an integer of 2 or more), and N sub-ADCs 200-1 to 200-N are arranged.

An analog input signal in is simultaneously applied to the N sub-ADCs 200-1 to 200-N. On the other hand, a clock signal ck with a cycle Tck is applied so that the timing is delayed by τck between the sub-ADCs. In order to realize such a timing shift, delay circuits 201-1 to 201-(N−1) with the delay time τck are inserted one by one into clock lines between the sub-ADCs. Here, the delay circuits 201-1 to 201-(N−1) are designed such that the delay time τck satisfies the following formula.

τck=1/N×Tck (2)

The delay circuits 201-1 to 201-(N−1) are realized by, for example, an inverter chain circuit including a transistor, a resistor, and the like.

An operation of the above time interleaved ADC will be described. When a time at which the sub-ADC 200-1 samples the analog input signal in is 0, a clock signal delayed by τck from the sub-ADC 200-1 is applied to the sub-ADC 200-2. Therefore, the sub-ADC 200-2 samples the analog input signal in at time point τck. At time point N×τck=Tck, the sub-ADC 200-1 performs sampling again.

At time τck×K (where K is an integer of 0 or more), any one of the sub-ADCs 200-1 to 200-N performs sampling. Therefore, a sampling interval of the entire time interleaved ADC is τck. That is, the cycle of the input clock signal ck is Tck, and sampling can be performed in the cycle τck shorter than Tck in the entire circuit while each sub-ADC also operates in the cycle Tck. Therefore, a sampling rate of the time interleaved ADC is N times the sampling rate of each sub-ADC.

The digital output signals out-1 to out-N of the sub-ADCs 200-1 to 200-N are usually integrated by a digital signal processing circuit or the like at a subsequent stage.

To generalize above description, in the time interleaved ADC, the following formula is established when a sampling rate is fs and a clock frequency is fck=1/Tck.

fs=fck×N (3)

That is, in the time interleaved ADC, by increasing the number of interleaves N, even in a case where a relatively delayed clock signal ck is used, a sampling rate that is N times the clock frequency fck can be obtained. Thus, design requirements for a clock generation circuit or an ADC can be relaxed.

However, in the time interleaved ADC, as is clear from Formula (3), in order to achieve the sampling rate fs higher than the clock frequency fck, it is necessary to increase the number of interleaves N. In the time interleaved ADC, since the N sub-ADCs are connected in parallel to an input signal source, the overall input impedance becomes 1/N of the input impedance of one sub-ADC, and thus the overall input load increases to N times that in the case of one sub-ADC. Thus, in the time interleaved ADC, there is a problem that a large amount of current flows from the input signal source and influences an operation of the input signal source, or an input band is narrowed, and input characteristics deteriorate.

### CITATION LIST

### Non Patent Literature

Non Patent Literature 1: W. C. Black and D. A. Hodges, “Time Interleaved Converter Arrays”, IEEE Journal of Solid-State Circuits, vol. SC-15, no. 612, pp. 1022-1029, December 1980

### SUMMARY

### Technical Problem

Embodiments of the present invention have been made to solve the above problems, and an object of embodiments of the present invention is to provide a time interleaved ADC capable of maintaining favorable input characteristics without increasing a load on an input signal source with respect to an increase in the number of interleaves.

### Solution to Problem

According to embodiments of the present invention, there is provided a time interleaved ADC including a plurality of ADCs configured to sample an analog input signal at a timing synchronized with a clock signal to convert the analog input signal into a digital output signal; a plurality of first delay circuits configured to apply a time difference to the analog input signal such that the analog input signal is input to each ADC with a delay of a first delay time in an arrangement order of the plurality of ADCs; and a plurality of second delay circuits configured to apply a time difference to the clock signal such that the clock signal is input to each ADC with a delay of a second delay time in the arrangement order of the plurality of ADCs.

Further, according to embodiments of the present invention, there is provided a time interleaved ADC including a plurality of ADCs configured to sample an analog input signal at a timing synchronized with a clock signal to convert the analog input signal into a digital output signal; a plurality of first delay circuits configured to apply a time difference to the analog input signal such that the analog input signal is input to each ADC with a delay of a first delay time in an arrangement order of the plurality of ADCs; and a plurality of second delay circuits configured to apply a time difference to the clock signal such that the clock signal is input to each ADC with a delay of a second delay time in an input order reverse to that of the analog input signal.

### Advantageous Effects of Embodiments of Invention

According to embodiments of the present invention, by providing the first delay circuit and the second delay circuit, it is possible to realize a time interleaved ADC capable of maintaining favorable input characteristics without increasing a load on an input signal source with respect to an increase in the number of interleaves.

### BRIEF DESCRIPTION OF THE DRAWINGS

FIG. 1 is a block diagram illustrating a configuration of a time interleaved ADC according to a first embodiment of the present invention.

FIG. 2 is a block diagram illustrating another configuration of the time interleaved ADC according to the first embodiment of the present invention.

FIG. 3 is a block diagram illustrating a configuration of a time interleaved ADC according to a second embodiment of the present invention.

FIG. 4 is a block diagram illustrating a configuration of a time interleaved ADC according to a third embodiment of the present invention.

FIG. 5 is a block diagram illustrating another configuration of the time interleaved ADC according to the third embodiment of the present invention.

FIG. 6 is a block diagram illustrating a configuration of a time interleaved ADC according to a fourth embodiment of the present invention.

FIG. 7 is a block diagram illustrating another configuration of the time interleaved ADC according to the fourth embodiment of the present invention.

FIG. 8 is a block diagram illustrating a configuration of a time interleaved ADC according to a fifth embodiment of the present invention.

FIG. 9 is a diagram for describing the operation of the ADC.

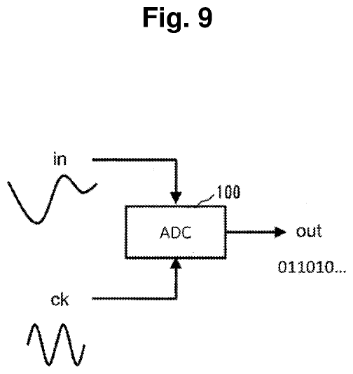

FIG. 10 is a block diagram illustrating a configuration of a time interleaved ADC.

### DETAILED DESCRIPTION OF ILLUSTRATIVE EMBODIMENTS

### First Embodiment

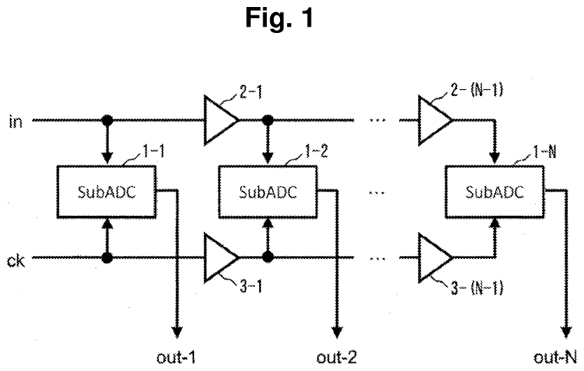

Hereinafter, embodiments of the present invention will be described with reference to the drawings. FIG. 1 is a block diagram illustrating a configuration of a time interleaved ADC according to a first embodiment of the present invention. The time interleaved ADC of the present embodiment includes N (where N is an integer of 2 or more) sub-ADCs 1-1 to 1-N that sample an analog input signal at a timing synchronized with a clock signal to convert the analog input signal into digital output signals out-1 to out-N, delay circuits 2-1 to 2-(N−1) that apply a time difference to the analog input signal such that the analog input signal is input to the individual sub-ADCs 1-1 to 1-N with a delay of a first delay time τin in the arrangement order of the sub-ADCs 1-1 to 1-N, and delay circuits 3-1 to 3-(N−1) that apply a time difference to the clock signal such that the clock signal is input to the individual sub-ADCs 1-1 to 1-N with a delay of a second delay time τck in the arrangement order of the sub-ADCs 1-1 to 1-N.

The analog input signal in is input from an input signal source (not illustrated) to the time interleaved ADC. The clock signal ck is input from a clock generation circuit (not illustrated) to the time interleaved ADC.

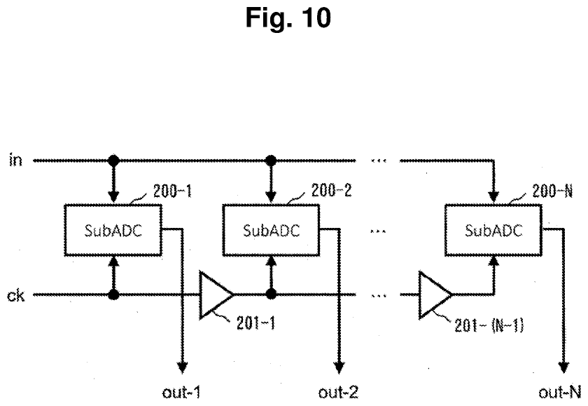

A difference from the ADC illustrated in FIG. 10 is that the delay circuits 2-1 to 2-(N−1) are provided between the sub-ADCs not only for the clock signal but also for the analog input signal. A delay time of the delay circuit 2-i between the sub-ADC 1-i (where i is an integer of 1 to (N−1)) and the sub-ADC 1-(i+1) is τin(i), and a delay time of the delay circuit 3-i is τck(i). The delay times τin(i) of the respective delay circuits 2-i may have different values or the same value. Similarly, the delay times τck(i) of the respective delay circuits 3-i may have different values or the same value.

All the delay circuits 2-i and 3-i are designed such that the delay times τin(i) and τck(i) satisfy the following formula.

|τin(i)−τck(i)|=1/N×Tck (4)

As described above, N is the number of interleaves, and Tck is the clock cycle. In particular, in the most typical form, the ADC is designed to satisfy the following formula:

τck(i)−τin(i)=1/N×Tck (5)

In the present embodiment, since a relative difference between the delay times of the analog input signal and the clock signal is 1/N×Tck in each of the sub-ADCs 1-2 to 1-N, it is possible to obtain a sampling rate that is N times the clock frequency, similarly to the conventional time interleaved ADC.

As will be obvious, if τin(i)=0 is set for all i, a configuration equivalent to that of the conventional time interleaved ADC illustrated in FIG. 10 is obtained, and Formula (4) coincides with Formula (2).

A feature of the present embodiment is that an input signal source only needs to drive the sub-ADC 1-1 and the delay circuit 2-1 at the first stage regardless of the number of interleaves N. That is, a load on the input signal source does not increase even if the number of interleaves N increases unlike the conventional time interleaved ADC. In addition, each delay circuit 2-i only needs to drive the sub-ADC 1-(i+1) and the delay circuit 2-(i+1) at the next stage. Therefore, the time interleaved ADC of the present embodiment can maintain favorable input characteristics even when the number of interleaves N increases.

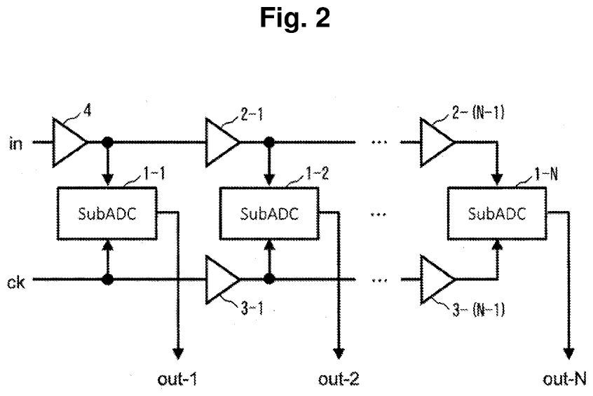

In order to maintain more favorable input characteristics, an input buffer may be provided between the input signal source that outputs the analog input signal in and the analog input signal terminal of the sub-ADC 1-1 at the first stage. A configuration in this case is illustrated in FIG. 2. In the case of the configuration in FIG. 2, the input signal source only needs to drive an input buffer 4.

### Second Embodiment

The first embodiment has the following problem. In the case of designing a time interleaved ADC that achieves a desired sampling rate, values of the number of interleaves N and the clock cycle Tck are determined by the determined specification, and thus the delay times τin(i) and τck(i) of the delay circuits 2-i and 3-i may be determined such that Formula (5) is established.

A problem of the first embodiment is that the delay time τck(i) of the delay circuit 3-i is longer than the delay time 1/N×Tck of the conventional delay circuit 201-i by τin(i).

In general, characteristics such as a delay time of a circuit vary depending on accuracy of a circuit manufacturing technique, fluctuation in a temperature during operation, fluctuation in a power supply voltage, and the like. For example, even if the variation is 1% or 3%, an absolute value of the variation increases as the delay time τck(i) increases.

When the variation in the delay time of the delay circuit 3-i increases, a sampling timing error of each sub-ADC is caused. That is, an input signal is sampled at a timing shifted from a time point at which the analog input signal should originally be sampled, and an error is superimposed on an output waveform due to the deviation in timing. The larger the timing error, the larger the error of the output waveform, and the performance of the ADC deteriorates.

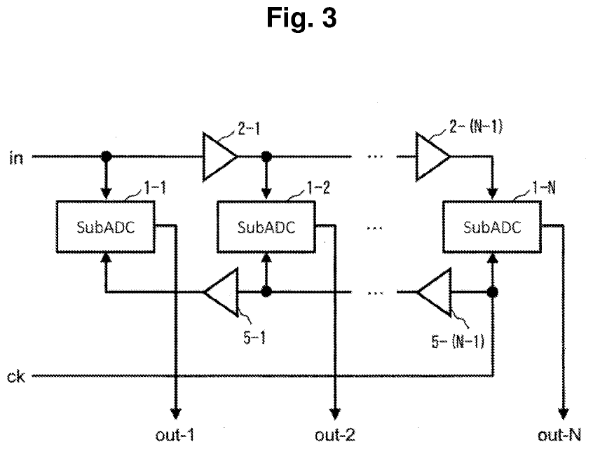

The second embodiment of the present invention is directed to solving the problem of the first embodiment. FIG. 3 is a block diagram illustrating a configuration of a time interleaved ADC according to the present embodiment. The time interleaved ADC of the present embodiment includes sub-ADCs 1-1 to 1-N, delay circuits 2-1 to 2-(N−1), and delay circuits 5-(N−1) to 5-1 that apply a time difference to a clock signal such that the clock signal is input to the individual sub-ADCs 1 to 1-1 with a second delay time τck in an input order reverse to the analog input signal.

Similarly to the first embodiment, the analog input signal is input to the sub-ADCs 1-1, 1-2, . . . , and 1-N in this order. On the other hand, the clock signal is input to the sub-ADCs 1-N, . . . , 1-2, and 1-1 in this order. That is, the second embodiment is different from the first embodiment in that the order of input to the individual sub-ADCs is reversed between the analog input signal and the clock signal.

Similarly to the first embodiment, a delay time of the delay circuit 2-i between the sub-ADC 1-i (where i is an integer from 1 to (N−1)) and the sub-ADC 1-(i+1) is τin(i). In addition, a delay time of the delay circuit 5-(i) between the sub-ADC 1-i and the sub-ADC 1-(i+1) is τck(i). The delay times τck(i) of the delay circuits 5-i may have different values or the same value.

All the delay circuits 2-i and 5-i are designed such that the delay times τin(i) and τck(i) satisfy the following formula.

τin(i)+τck(i)=1/N×Tck (6)

By designing the delay circuits 2-i and 5-i s to satisfy Formula (6), it is possible to obtain a sampling rate that is N times the clock frequency, similarly to the conventional time interleaved ADC and the first embodiment.

As can be seen from Formula (6), a feature of the present embodiment is that the delay time τck(i) of the delay circuit 5-i can be set to a value shorter than the delay time 1/N×Tck of the conventional delay circuit 201-i. Therefore, in the present embodiment, an error in the delay time of the delay circuit 5-i can be reduced compared with the conventional time interleaved ADC or the first embodiment. As a result, it is possible to design an ADC with high accuracy.

In the same manner as in the first embodiment, an input buffer may be provided between the input signal source and the analog input signal terminal of the sub-ADC 1-1 at the first stage.

### Third Embodiment

Regarding the variation in the delay time described in the second embodiment, in both the first and second embodiments, it is conceivable to make the delay time of the delay circuit for either the analog input signal or the clock signal or the delay circuit for both the analog input signal and the clock signal variable according to a control signal input from the outside. By making the delay time variable, variations in the delay time can be calibrated in a use state after manufacturing the circuit.

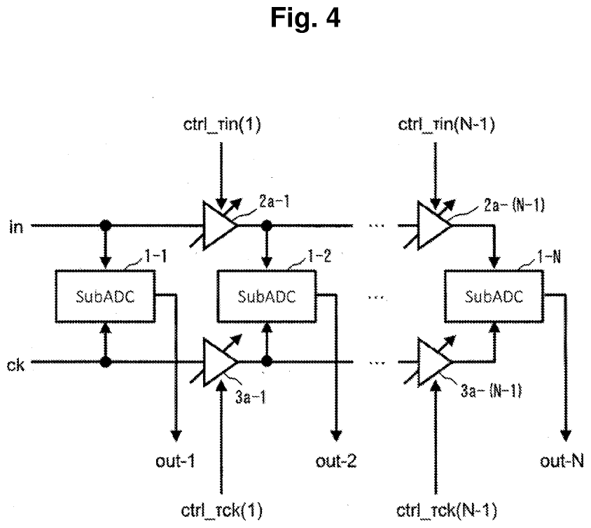

FIG. 4 is a block diagram illustrating a configuration of a time interleaved ADC according to a third embodiment of the present invention. The time interleaved ADC of the present embodiment includes sub-ADCs 1-1 to 1-N and variable delay circuits 2a-1 to 2a-(N−1) and 3a-1 to 3a-(N−1).

The configuration in FIG. 4 is obtained by replacing the delay circuits 2-1 to 2-(N−1) with the variable delay circuits 2a-1 to 2a-(N−1) and replacing the delay circuits 3-1 to 3-(N−1) with the variable delay circuits 3a-1 to 3a-(N−1) in the first embodiment.

The delay time τin(i) of the variable delay circuit 2a-i between the sub-ADC 1-i (where i is an integer from 1 to (N−1)) and the sub-ADC 1-(i+1) can be adjusted by using a delay control signal ctrl_τin(i). Similarly, the delay time τck(i) of the variable delay circuit 3a-i can be adjusted by using the delay control signal ctrl_τck(i).

By adjusting the delay control signals ctrl_τin(i) and ctrl_τck(i) such that noise of the output signals out-1 to out-N due to errors of the delay times τin(i) and τck(i) is minimized while observing the signals out-1 to out-N actually output from the time interleaved ADC, it is possible to manufacture a highly accurate ADC.

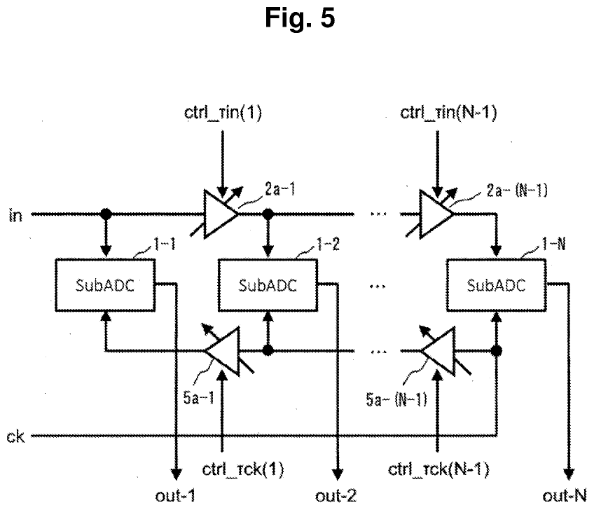

FIG. 5 illustrates a configuration in a case where the present embodiment is applied to the second embodiment. The configuration in FIG. 5 is obtained by replacing the delay circuits 2-1 to 2-(N−1) with the variable delay circuits 2a-1 to 2a-(N−1) and replacing the delay circuits 5-(N−1) to 5-1 with the variable delay circuits 5a-(N−1) to 5a-1 in the second embodiment.

In FIGS. 4 and 5, the delay times of the delay circuits for both the analog input signal and the clock signal are variable, but the delay circuit for only one of the analog input signal and the clock signal may be a variable delay circuit.

In the same manner as in the first embodiment, an input buffer may be provided between the input signal source and the analog input signal terminal of the sub-ADC 1-1 at the first stage.

### Fourth Embodiment

In the first to third embodiments, analog input signals input to the individual sub-ADCs all need to have the same waveform except for different time delays. That is, all gains of the delay circuits for the analog input signal are required to be 1. However, in a case where the gains of the individual delay circuits are shifted due to the influence of the circuit variation, the analog input signal input to the subsequent sub-ADC integrates gain errors, and thus noise superimposed on the output signal increases. Regarding such variations in the gain of the delay circuit, it is conceivable to make the gain (amplification factor) of the delay circuit variable such that the mismatch between the gains of the sub-ADCs can be calibrated to some extent.

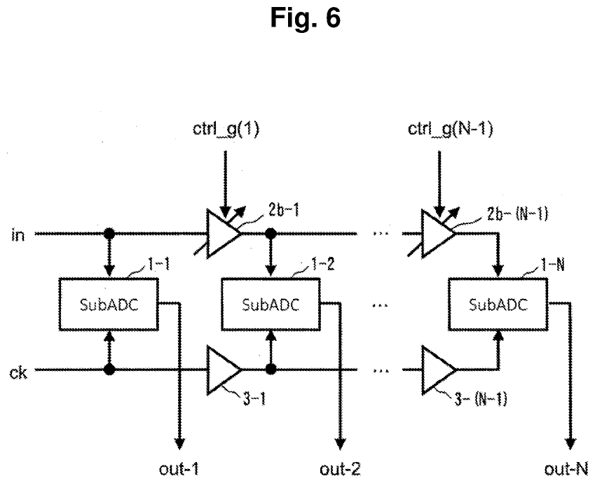

FIG. 6 is a block diagram illustrating a configuration of a time interleaved ADC according to a fourth embodiment of the present invention. The time interleaved ADC of the present embodiment includes sub-ADCs 1-1 to 1-N, delay circuits 2b-1 to 2b-(N−1) of which gains can be adjusted by using a gain control signal input from the outside, and delay circuits 3-1 to 3-(N−1).

The configuration in FIG. 6 is obtained by replacing the delay circuits 2-1 to 2-(N−1) in the first embodiment with the delay circuits 2b-1 to 2b-(N−1).

A gain of the delay circuit 2b-i between the sub-ADC 1-i (where i is an integer from 1 to (N−1)) and the sub-ADC 1-(i+1) can be adjusted by using a gain control signal ctrl_g(i). The delay circuit 2b-i can be realized by, for example, a combination of a delay circuit including an inverter chain circuit and the like and a variable gain amplifier.

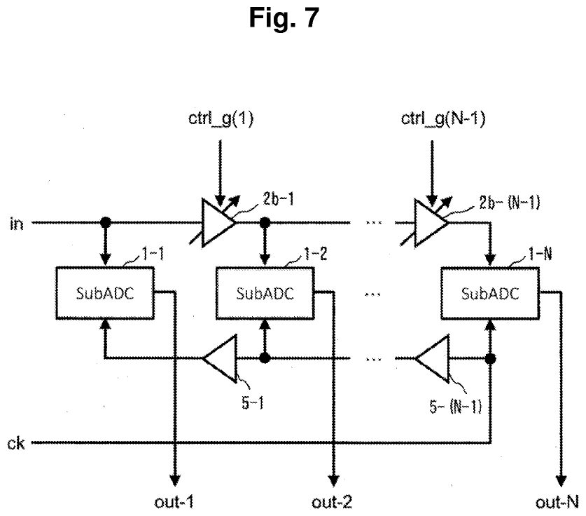

FIG. 7 illustrates a configuration in a case where the present embodiment is applied to the second embodiment.

The present embodiment may be combined with the third embodiment. That is, in FIGS. 6 and 7, the delay circuits 2b-1 to 2b-(N−1) may be variable delay and variable gain delay circuits. In addition, the delay circuits 3-1 to 3-(N−1) and 5-1 to 5-(N−1) may be variable delay circuits.

In the same manner as in the first embodiment, an input buffer may be provided between the input signal source and the analog input signal terminal of the sub-ADC 1-1 at the first stage.

### Fifth Embodiment

In the first to fourth embodiments, the analog input signal passes through the delay circuits 2-1 to 2-(N−1), 2a-1 to 2a-(N−1), and 2b-1 to 2b-(N−1). Thus, the output signals out-1 to out-N of the individual sub-ADCs 1-1 to 1-N are output at timings relatively shifted by the delay times of the delay circuits 2-1 to 2-(N−1), 2a-1 to 2a-(N−1), and 2b-1 to 2b-(N−1). Processing of the digital signal processing circuit that integrates the output signals out-1 to out-N becomes complicated due to a timing shift between the output signals out-1 to out-N. In order to simplify the processing of the digital signal processing circuit, it is conceivable to provide a delay circuit for correcting a time difference between the output signals out-1 to out-N at an output of each sub-ADC.

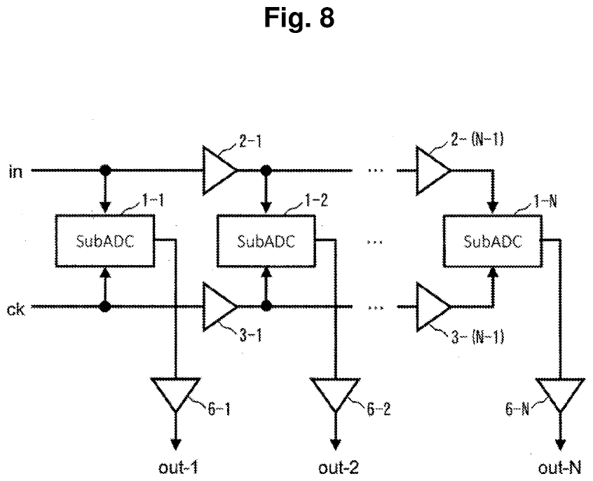

FIG. 8 is a block diagram illustrating a configuration of a time interleaved ADC according to a fifth embodiment of the present invention. The time interleaved ADC of the present embodiment includes sub-ADCs 1-1 to 1-N, delay circuits 2-1 to 2-(N−1) and 3-1 to 3-(N−1), and delay circuits 6-1 to 6-N that are provided at the outputs of the sub-ADCs 1-1 to 1-N, respectively, and correct time differences between output signals out-1 to out-N of the sub-ADCs 1-1 to 1-N.

For example, the sub-ADC 1-2 receives the analog input signal delayed by τin(1) from the sub-ADC 1-1. Therefore, the output signal out-2 of the sub-ADC 1-2 is delayed by τin(1) compared with the output signal out-1 of the sub-ADC 1-1. Therefore, if delay circuits 6-1 and 6-2 are provided at the outputs of the sub-ADCs 1-1 and 1-2, respectively, and a delay time of the output of the sub-ADC 1-1 is made longer than a delay time of the output of the sub-ADC 1-2 by τin(1), the outputs of the sub-ADCs 1-1 and 1-2 can be processed on the same time axis.

When the description of the sub-ADCs 1-1 and 1-2 is generalized for all the sub-ADCs 1-1 to 1-N, the delay circuits 6-1 to 6-N are designed to satisfy the following conditions for all the integers M of 2 or more and N or less.

Equation 1

Σⱼ₌₁^{M-1}τᵢₙ(j)+τₒᵤₜ(M)=τₒᵤₜ(1) (7)

τout(1) is a delay time of the delay circuit 6-1 connected to the output of the sub-ADC 1-1, and τout(M) is a delay time of the delay circuit 6-M connected to the output of the sub-ADC 1-M (where M is an integer of 2 to N).

As described above, in the present embodiment, since the output signals out-1 to out-N of the sub-ADCs 1-1 to 1-N can be processed on the same time axis, the subsequent processing is simplified.

In the example in FIG. 8, the present embodiment is applied to the first embodiment, but the delay circuits 6-1 to 6-N may be provided in the second to fourth embodiments.

In the same manner as in the first embodiment, an input buffer may be provided between the input signal source and the analog input signal terminal of the sub-ADC 1-1 at the first stage.

In the first to fifth embodiments, the analog input signal and the clock signal are single-phase signals, but either one of the analog input signal and the clock signal or both of the analog input signal and the clock signal may be differential signals. Consequently, it is expected to improve a signal-to-noise ratio by removing in-phase noise.

In a case where the analog input signal is a differential signal, the delay circuits 2-1 to 2-(N−1), 2a-1 to 2a-(N−1), and 2b-1 to 2b-(N−1) are differential input differential output delay circuits. The sub-ADCs 1-1 to 1-N are differential input ADCs.

In a case where the clock signal is a differential signal, the delay circuits 3-1 to 3-(N−1), 3a-1 to 3a-(N−1), 5-1 to 5-(N−1), and 5a-1 to 5a-(N−1) are differential input differential output delay circuits. The sub-ADCs 1-1 to 1-N are differential clock input ADCs.

### INDUSTRIAL APPLICABILITY

Embodiments of the present invention are applicable to an ADC.

### REFERENCE SIGNS LIST

1-1 to 1-N Sub-ADC
2-1 to 2-(N−1), 2b-1 to 2b-(N−1), 3-1 to 3-(N−1), 5-1 to 5-(N−1), 6-1 to 6-N Delay circuit
2a-1 to 2a-(N−1), 3a-1 to 3a-(N−1), 5a-1 to 5a-(N−1) Variable delay circuit
4 Input buffer.

1-5. (canceled)

6. A time interleaved ADC comprising:
a plurality of analog to digital converters (ADCs) configured to sample an analog input signal at a timing synchronized with a clock signal and convert the analog input signal into a digital output signal;
a plurality of first delay circuits configured to apply a time difference to the analog input signal such that the analog input signal is input to each of the plurality of ADCs according to a first delay time in an arrangement order of the plurality of ADCs; and
a plurality of second delay circuits configured to apply a time difference to the clock signal such that the clock signal is input to each of the plurality of ADCs according to a second delay time in the arrangement order of the plurality of ADCs.

7. The time interleaved ADC according to claim 6, wherein the plurality of first delay circuits is capable of adjusting a delay time based on a delay control signal input from outside the time interleaved ADC.

8. The time interleaved ADC according to claim 6, wherein the plurality of second delay circuits is capable of adjusting a delay time based on a delay control signal input from outside the time interleaved ADC.

9. The time interleaved ADC according to claim 6, wherein the plurality of first delay circuits is capable of adjusting a gain based a gain control signal input from outside the time interleaved ADC.

10. The time interleaved ADC according claim 6, further comprising:
a plurality of third delay circuits provided at respective outputs of the plurality of ADCs and configured to correct a time difference between output signals of the plurality of ADCs.

11. A time interleaved ADC comprising:
a plurality of analog to digital converters (ADCs) configured to sample an analog input signal at a timing synchronized with a clock signal and convert the analog input signal into a digital output signal;
a plurality of first delay circuits configured to apply a time difference to the analog input signal such that the analog input signal is input to each of the plurality of ADCs with a delay of a first delay time in an arrangement order of the plurality of ADCs; and
a plurality of second delay circuits configured to apply a time difference to the clock signal such that the clock signal is input to each of the plurality of ADCs with a delay of a second delay time in an input order reverse to that of the analog input signal.

12. The time interleaved ADC according to claim 11, wherein the plurality of first delay circuits is capable of adjusting a delay time based on a delay control signal input from outside the time interleaved ADC.

13. The time interleaved ADC according to claim 11, wherein the plurality of second delay circuits is capable of adjusting a delay time based on a delay control signal input from outside the time interleaved ADC.

14. The time interleaved ADC according to claim 11, wherein the plurality of first delay circuits is capable of adjusting a gain based a gain control signal input from outside the time interleaved ADC.

15. The time interleaved ADC according claim 11, further comprising:
a plurality of third delay circuits provided at respective outputs of the plurality of ADCs and configured to correct a time difference between output signals of the plurality of ADCs.

16. A method of operating a time interleaved ADC, the method comprising:
sampling, by a plurality of analog to digital converters (ADCs), an analog input signal at a timing synchronized with a clock signal;
converting, by the plurality of ADCs, the analog input signal into a digital output signal;
applying, by a plurality of first delay circuits, a time difference to the analog input signal such that the analog input signal is input to each of the plurality of ADCs according to a first delay time in an arrangement order of the plurality of ADCs; and
applying, by a plurality of second delay circuits, a time difference to the clock signal such that the clock signal is input to each of the plurality of ADCs according to a second delay time in the arrangement order of the plurality of ADCs or according to a third delay time in an arrangement order that is reverse of the arrangement order of the plurality of ADCs.

17. The method according to claim 16, further comprising adjusting, by the plurality of first delay circuits, the first delay time based on a delay control signal input from outside the time interleaved ADC.

18. The method according to claim 16, further comprising adjusting, by the plurality of second delay circuits, the second delay time based on a delay control signal input from outside the time interleaved ADC.

19. The method according to claim 16, further comprising adjusting, by the plurality of first delay circuits, a gain based a gain control signal input from outside the time interleaved ADC.

20. The method according to claim 16, further comprising:
correcting, by a plurality of third delay circuits provided at respective outputs of the plurality of ADCs, a time difference between output signals of the plurality of ADCs.
